(19) United States
(12) Patent Application Publication
(10) Pub. No.: US 2008/0183406 A1
(43) Pub. Date: Jul. 31, 2008

(54) Online IED Fault Diagnosis Device and Method for Substation Automation System Based on IEC61850

(75) Inventors: Seung Jae Lee, Gyeonggi-do (KR); Seong Jeong Rim, Seoul (KR); Seong II Lim, Gyeonggi-do (KR)

Correspondence Address: THE WEBB LAW FIRM, P.C., 700 KOPPERS BUILDING, 436 SEVENTH AVENUE, PITTSBURGH, PA, 15219, US

(73) Assignee: Myongji University Industry and Academia Cooperation Foundation, Gyeonggi-do (KR)

(21) Appl. No.: 12/021,501

(22) Filed: Jan. 29, 2008

(30) Foreign Application Priority Data
Jan. 30, 2007 (KR) 10-2007-0009607

(51) Int. Cl. G01R 31/02

(52) U.S. Cl. 702/58

(57) ABSTRACT

Disclosed is a fault diagnosis device for diagnosing a fault in a bay Intelligent Electronic Device (IED) for a substation automation system, which includes an online IED diagnosis device and a backup IED. The online IED diagnosis device includes an IED selection unit, an IED switch unit, a fault diagnosis, and a result display unit. With reference to a Substation Configuration Description (SCD) file, the online IED diagnosis device designates an IED to be tested, and extracts backup information for the IED to be tested. A backup IED replaces the operation of the IED to be tested based on the extracted backup information. Further, the online IED diagnosis device determines the occurrence or non-occurrence of a fault in the IED to be tested by analyzing response information received in response to transmission of a test pattern to the IED to be tested.

### BACKGROUND OF THE INVENTION

1. Field of the Invention

The present invention relates generally to a substation automation system based on IEC61850, and, more particularly, to an online Intelligent Electronic Device (IED) fault diagnosis device and method for a substation automation system, which diagnoses the occurrence of a fault in an IED by inspecting the IED online from outside the system in compliance with the IEC61850 standard without adding additional software or hardware to the IED while the corresponding IED is not separated from the system, the function of the IED is not disabled, and the normal function thereof is continuously performed during the inspection for the IED.

2. Description of the Related Art

An electric power system for providing electric power to households, factories, or buildings includes an electric power plant for producing electric power, one or more transmission lines for transmitting electric power, one or more substations for transforming the amplitude of electric power into desired amplitude and one or more distribution lines for distributing electric power to respective areas that require electric power. Such a substation includes electric power equipment, such as transformer, bus, line, and circuit breaker. A transformer transforms the amplitude of voltage to be transmitted, a bus connects transmission lines, and a circuit breaker opens and closes an electric power flow through a transmission line. IEDs are intelligent electronic devices which are installed in a substation and are configured to monitor, control, and protect various types of electric power equipment. Computers may be used as the IEDs. If a fault occurs in such an IED, it is difficult to properly monitor, control, and protect electric power equipment, and thus it is difficult to smoothly supply electric power.

In a conventional substation, respective IEDs are directly connected to electric power equipment and independently operated. However, recently, a substation automation system in which respective IEDs share information with each other has been adopted. IEC61850 is an international standard for substation automation communication architecture that was proposed in order to implement effective communication between heterogeneous IEDs installed in a substation. IEC61850 has been established as the only international standard for substation automation, and all IEDs are expected to follow international standard IEC61850 from now on.

Meanwhile, diagnosing a fault in an IED is very important in order to operate a substation automation system. A currently used method of diagnosing a fault in an IED is a method of separating an IED to be tested from a system and then inspecting it using an IED test device. Although this method has an advantage in that an IED can be comprehensively and accurately inspected for faults, it has the following disadvantages.

First, since a person must periodically perform inspection while traveling around with necessary devices, a problem occurs in that the cycle of inspection is considerably long. If the cycle of inspection is long, it is difficult to detect a fault in an IED immediately when a fault occurs in the IED. When a fault occurs in an IED and a system fault occurs in electric power equipment, a serious problem occurs in that the electric power equipment cannot be properly monitored, controlled, or protected.

Second, while an IED is inspected, the IED to be tested must be separated from a substation automation system. Therefore, if a fault occurs in electric power equipment while the IED to be tested is separated from the substation automation system for inspection, the electric power equipment cannot be properly monitored, controlled, or protected, thereby causing a serious problem.

Further, another prior art technology for detecting a fault in an IED includes self-diagnostic functionality. Although a method using a computer device having self-diagnostic functionality, such as a digital IED, has been widely used, it has the following disadvantages.

First, since the method of detecting a fault in an IED using self-diagnostic functionality can detect a fault in an IED only when all IEDs are operating normally, a problem occurs in that the entire system must be driven in order to detect a fault of an IED.

Second, since system resources are used in order to use self-diagnostic functionality when an IED is operated, the performance of the function of the IED may be deteriorated, with the result that, if hardware is augmented so as to compensate for the deterioration, a problem occurs in that the cost of a product is increased.

Third, when a fault occurs in an IED, problems occur in that the results of self-diagnosis of the IED are unreliable, and in that the process of diagnosing a fault is complicated because a self-diagnosis method has not been standardized.

Fourth, since a method of outputting the results of self-diagnosis has not been standardized, a problem occurs in that it is difficult for the operator of a substation automation system to remotely monitor the status of IEDs in a substation.

As described above, if the occurrence of a fault in an IED is not detected when a fault occurs in one of the IEDs of a substation automation system, the extent of damage spreads to sound systems of electric power equipment because proper management is not performed even when a disturbance occurs in the electric power equipment. Currently, an IED to be tested is inspected offline at considerably long cycles while the function of the IED to be tested is disabled, or self-diagnosis functionality is used while a system is driven. However, a technology for more conveniently and reliably diagnosing a fault in an IED is demanded in order to solve the above-described problems.

### SUMMARY OF THE INVENTION

Accordingly, the present invention has been made keeping in mind the above problems occurring in the prior art, and an object of the present invention is to provide an online IED fault diagnosis device and method for a substation automation system, which diagnoses the occurrence of a fault in an IED by inspecting the IED online from outside the IED in compliance with the IEC61850 standard in order to accurately and reliably diagnose a fault in the IED without increasing expenses.

In order to accomplish the above object, the present invention provides a fault diagnosis device for diagnosing a fault in a bay Intelligent Electronic Device (IED) for a substation automation system, including an online IED diagnosis device for, with reference to a Substation Configuration Description (SCD) file received from the station device of the substation automation system, designating an IED to be tested, and extracting backup information for the IED to be tested; and a backup IED for replacing the operation of the IED to be tested based on the extracted backup information; wherein the online IED diagnosis device determines the occurrence or non-occurrence of a fault in the IED to be tested by analyzing response information received in response to the transmission of a test pattern to the IED to be tested.

The backup IED includes a file processing unit for receiving backup information from the online diagnosis device; and a program management unit for sorting and managing the backup information received by the file processing unit, and enabling or disabling a service operation of the IED to be tested based on the backup information.

The backup information includes control state information about the corresponding bay IED for monitoring, controlling, and protecting the substation automation system.

The online IED diagnosis device includes an IED selection unit for designating the IED to be tested from an IED list extracted from the SCD file; an IED switch unit for extracting the backup information for the IED to be tested from the IED list, and transmitting it to the backup IED; a fault diagnosis unit for transmitting the test pattern to the IED to be tested, receiving the response information from the IED to be tested in response to the transmitted test pattern, and determining the occurrence or non-occurrence of a fault in the IED to be tested by analyzing the received response information; and a result display unit for displaying the determined occurrence or non-occurrence of a fault on a user interface.

The fault diagnosis unit manages test patterns for controlling the service state information for the respective bay IEDs, and transmits one or more test patterns to the IED to be tested in response to the request of a user. The fault diagnosis unit can automatically select test patterns prepared in advance for the respective bay IEDs included in the IED list extracted from the SCD file in sequence. The fault diagnosis unit manages an estimated response for a service result provided by the corresponding IED based on the transmitted test pattern, and determines occurrence or non-occurrence of a fault by comparing the received response information with the estimated response.

In order to accomplish the above object, the present invention provides a fault diagnosis device for a substation automation system, the substation automation system including one or more station devices, one or more bay IEDs connected to the station device through a station bus based on the Ethernet, and one or more process IEDs connected to the respective bay IEDs though a process bus based on the Ethernet and configured to manage the one or more pieces of the electric power equipment of a substation, wherein: the fault diagnosis device is connected to the station devices, the bay IEDs and the process IEDs based on the Ethernet; the fault diagnosis device designates an IED to be tested from a bay IED list extracted from an SCD file received from the station device, and causes a backup IED to replace operation of the IED to be tested; and the fault diagnosis device transmits a test pattern to the IED to be tested, and determines the occurrence or non-occurrence of a fault in the IED to be tested by inspecting response information received from the IED to be tested.

In order to accomplish the above object, the present invention provides a fault diagnosis method of diagnosing a fault in a bay IED for a substation automation system, the method including receiving an SCD file from the station device of the substation automation system; extracting an IED list from the received SCD file and designating an IED to be tested; causing a backup IED to replace the operation of the IED to be tested based on backup information for the IED to be tested; transmitting a test pattern to the IED to be tested; receiving response information from the IED to be tested in response to the transmitted test pattern; determining the occurrence or non-occurrence of a fault in the IED to be tested by inspecting the received response information; and displaying the determined occurrence or non-occurrence of a fault on a user interface.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a block diagram showing a substation automation system using a fault diagnosis device according to an embodiment of the present invention;

FIG. 2 is a view showing the Ethernet ports of the fault diagnosis device of FIG. 1;

FIG. 3 is a block diagram showing the fault diagnosis device of FIG. 1 in detail; and

FIG. 4 is a flowchart showing the operation of the fault diagnosis device of FIG. 1.

### DESCRIPTION OF THE PREFERRED EMBODIMENTS

Reference now should be made to the drawings, in which the same reference numerals are used throughout the different drawings to designate the same or similar components.

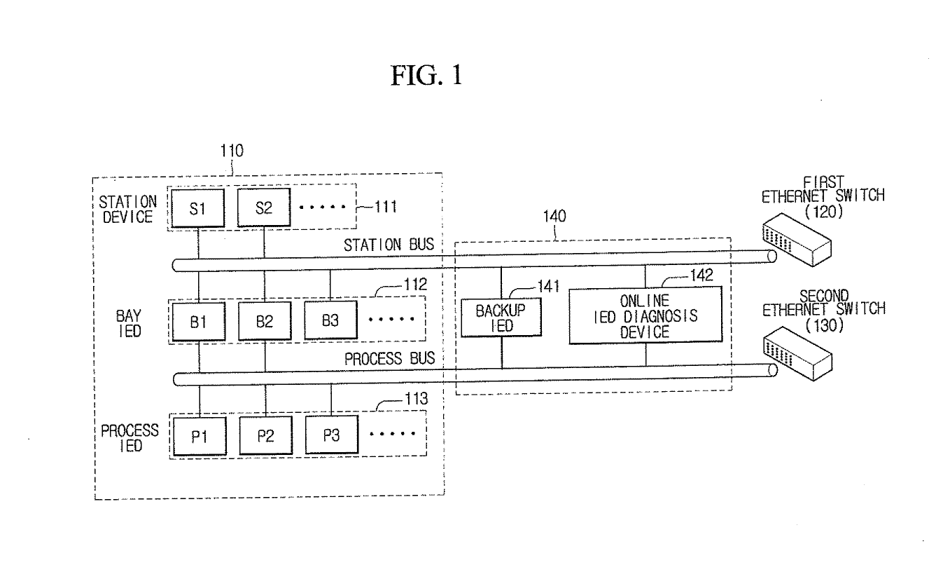

Hereinafter, embodiments of the present invention will be described in detail with reference to FIGS. 1 to 4.

FIG. 1 is a block diagram showing a substation automation system 110 using a fault diagnosis device 140 according to an embodiment of the present invention.

Referring to FIG. 1, the substation automation system 110 includes one or more station devices 111, one or more bay IEDs 112, and one or more process IEDs 113. Each of the station devices 111 and each of the bay IEDs 112 is connected to a first Ethernet switch 120 through a station bus for communication. Each of the bay IEDs 112 and the process IEDs 113 is connected to a second Ethernet switch 130 through a process bus for communication.

The fault diagnosis device 140 according to the present invention is a device which diagnoses the occurrence of a fault in the bay IED 112 online in compliance with the IEC61850 standard, and includes a backup IED 141 and an online diagnosis device 142.

First, the process IEDs 113 are connected to respective systems of electric power equipment, such as a transformer, a bus, a line, and a circuit breaker, in a substation. Further, one or more process IEDs P1, P2, P3, . . . can be installed to correspond to the respective electric power equipment. The communication between each of the bay IEDs 112 and each of the process IEDs 113, both of which are connected to the second Ethernet switch 130, is relayed based on the Ethernet-based communication protocol of the second Ethernet switch 130. The process IEDs 113 can detect the status of the respective systems of the electric power equipment, such as a transformer, a bus, a line, and a circuit breaker, on which monitor, control, and protection will be performed, under the control of the bay IED 112 connected through the second Ethernet switch 130 based on the Ethernet-based communication protocol.

The communication between each of the bay IEDs 112 and each of the station devices 111, both of which are connected to the first Ethernet switch 120, is relayed based on the Ethernet-based communication protocol of the first Ethernet switch 120. The bay IED 112 provides service, such as monitor, control, and protection for the respective pieces of electric power equipment in a substation by controlling the process IED 113 in response to the control information from the station device 111 connected based on the Ethernet-based communication protocol through the first Ethernet switch 120. That is, the bay IED 112 performs a function of monitoring whether a transformer properly transforms the amplitude of transmission voltage, whether a bus is properly connected to a transmission line, or whether a circuit breaker correctly blocks the power flow of the line, of performing control such that the functions of the above-described equipment are properly performed, and of performing protection such that the functions are stably provided. On or more bay IEDs 112 B1, B2, B3, . . . can be installed to correspond to the respective process IEDs 113.

The station device 111 is a user interface, for example, a Man-Machine Interface (MMI), such as a computer. That is, the station device 111 can collect information about the status of the respective systems of electric power equipment, such as, a transformer, a bus, a line, and a circuit breaker, on which monitor, control, and protection will be performed, from the bay IED 112, and output control information such that the bay IED 112 controls the process IED 113. A plurality of station devices 111 S1, S2, . . . may be operated for a plurality of operators.

The station device 111, the bay IED 112, and the process IED 113 communicate with each other through the first Ethernet switch 120 and the second Ethernet switch 130 according to the IEC61850 standard, which is substation automation communication architecture.

In the above-described configuration, if a fault occurs, particularly in the bay IED 112, it is difficult to properly monitor, control, and protect the respective systems of electric power equipment, so that it is difficult to smoothly supply power to desired areas. Therefore, unlike the prior art, the present invention proposes a fault diagnosis device 140 which can diagnose the fault of the bay IED 112 online from outside the substation automation system 110 in compliance with the IEC61850 standard. When the fault diagnosis device 140 diagnoses the fault in the bay IED 112, the fault diagnosis device 140 can diagnose a fault while the bay IED 112 is not separated from the system, the function of the bay IED 112 is not disabled, and the normal function of the bay IED 112 is continuously performed during the inspection for the IED.

The fault diagnosis device 140 is connected to the station device 111, the bay IED 112, and the process IED 113 through the first Ethernet switch 120 and the second Ethernet switch 130 based on the Ethernet protocol. Therefore, the fault diagnosis device 140 determines the occurrence or non-occurrence of a fault in the bay IED 112 based on a Substation Configuration Description (SCD: language which defines the configuration of a substation) file received from the station device 111 and written in interface language complying with the IEC61850 standard, so that the fault diagnosis device 140 can determine almost faults that may occur.

The SCD file is managed in the station device 111, and includes complete information about the functions of the respective IEDs installed in a substation, and about mutual communication methods therebetween. The fault diagnosis device 140 can extract information about IEDs installed in the substation, that is, an IED list about the bay IED 112, by analyzing the SCD file, designate an IED to be tested from the extracted bay IED list, cause the backup IED 141 to replace the operation of the IED to be tested, transmit a test pattern to the IED to be tested, and determines the occurrence or non-occurrence of a fault in the IED to be tested by inspecting response information received from the IED to be tested.

Unlike the prior art, the present invention does not employ a method of adding additional software or hardware to an IED. That is, the fault diagnosis device 140 causes the backup IED 141 to replace the operation of the IED to be tested, and evaluates response information received from the IED to be tested, so that faults can be accurately and reliably detected at an inexpensive cost, and thus a convenient and excellent fault detection function can be expected to be realized, compared to the prior art. The fault diagnosis device 140 is fixedly installed and functions as part of the substation automation system 110, so that the soundness of an IED can always be displayed on the user interface of the station device 111, thereby providing considerable convenience on an operation level, such as the maintenance of a substation.

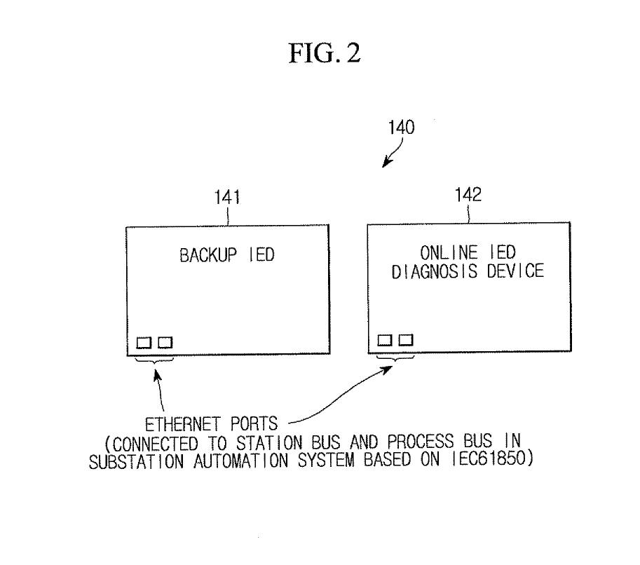

FIG. 2 is a view showing the Ethernet ports of the fault diagnosis device 140 of FIG. 1. As shown in FIG. 2, the backup IED 141 and online diagnosis device 142 of the fault diagnosis device 140 includes Ethernet ports to be connected to the respective first Ethernet switch 120 and second Ethernet switch 130 for communication through the respective station bus and process bus of the substation automation system 110 based on the IEC61850 standard.

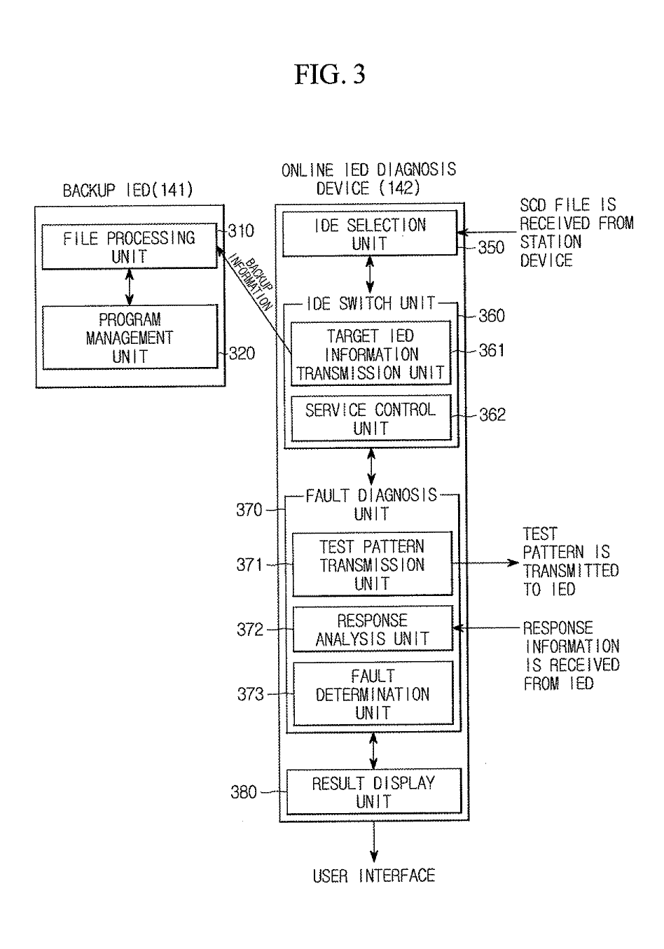

FIG. 3 is a block diagram showing the backup IED 141 and online diagnosis device 142 of the fault diagnosis device 140 of FIG. 1 in detail. Referring to FIG. 3, the backup IED 141 includes a file processing unit 310 and a program management unit 320. The online IED diagnosis device 142 includes an IED selection unit 350, an IED switch unit 360 having a target IED information transmission unit 361 and a service control unit 362, a fault diagnosis unit 370 having a test pattern transmission unit 371, a response analysis unit 372, and a fault determination unit 373, and a result display unit 380.

First, in the backup IED 141, the file processing unit 310 receives backup information about an IED to be tested from the target IED information transmission unit 361 of the online diagnosis device 142, and the backup information received from the file processing unit 310 is stored in and managed by the program management unit 320. The program management unit 320 can enable or disable a service operation of the IED to be tested based on the backup information. The backup information, which is control state information for an IED to be tested and which is used to monitor, control, and protect the substation automation system 110, includes logic node, service (for example, a control block), and set value information. All of this information is stored in the form of a file, and the backup IED 141 can perform the same function as that of the IED to be tested using these files. The program management unit 320 executes a program including the backup information such that the backup IED 141 performs the same function as the IED to be tested. When the diagnosis for the IED to be tested is terminated, the program management unit 320 can disable the program.

In the online diagnosis device 142, first, the IED selection unit 350 receives an SCD file from the station device 111 of the substation automation system 110, extracts an IED list from the received SCD file, and designates one IED from the extracted IED list as the IED to be tested. The IED list includes information about the respective bay IEDs 112 for monitoring, controlling, and protecting the substation automation system 110, that is, the IED list includes an address and control state information. Here, the address is used to select a fault diagnosis target IED, and the control state information is backup information used such that the backup IED 141 replaces the functions provided by the corresponding IED. In the SCD file, the control state information for each of the bay IEDs 112 includes service (for example, a control block) related to monitor, control, and protection, a logical node in a control block, and the set value of the logical node. In particular, the logical node is an object which indicates the basic unit function of exchanging data in IEC61850, and includes data for storing information and one or more methods of performing communication and functions. The type of logical node included in each of the bay IEDs 112 determines the function thereof.

The IED switch unit 360 includes the target IED information transmission unit 361 and the service control unit 362. The target IED information transmission unit 361 extracts backup information for an IED to be tested, for example, service, a logical node, and a set value, from the IED list, and transmits the extracted backup information to the backup IED 141. The backup IED 141, which received the copied backup information, as described above, performs the same function as the IED to be tested while fault diagnosis is performed. The service control unit 362 performs a function of performing control such that service, such as a control block or data set, included in the online diagnosis device 142 and the backup IED 141 is enabled or disabled.

Meanwhile, the fault diagnosis unit 370 includes the test pattern transmission unit 371, the response analysis unit 372, and the fault determination unit 373. The test pattern transmission unit 371 transmits one or more test patterns to a designated IED to be tested through the first Ethernet switch 120. For this purpose, the test pattern transmission unit 371 can manage test patterns for controlling the control state information (such control state information includes a control block, a logical node, and a set value) about the respective bay IEDs 112 in a database. A user can request fault diagnosis by selecting one or more test patterns from among the above-described test patterns. However, the operation of the test pattern transmission unit 371 is not limited to the above-described passive operation. That is, the test pattern transmission unit 371 can sequentially select test patterns prepared in advance for the respective bay IEDs 112 included in the IED list, so that fault diagnosis can be automatically performed on entire IEDs.

Therefore, an IED to be tested maintains or changes the existing function thereof based on the test pattern transmitted from the test pattern transmission unit 371, thereby providing service, such as monitor, control, and protection for the respective pieces of electric power equipment in the substation. Here, the IED to be tested monitors whether a transformer properly transforms the amplitude of transmission voltage, whether a bus is properly connected to a transmission line, or whether a circuit breaker correctly blocks the power flow of the line, performs control such that the functions thereof are properly performed, performs protection such that these functions are stably provided, and returns response information based on the results thereof. The response information is state information that indicates normal or abnormal states of respective electric power equipment systems.

The response analysis unit 372 receives the response information from the IED to be tested in response to the received test pattern, and compares the received response information with an estimated response. The fault determination unit 373 determines the occurrence or non-occurrence of a fault in the IED to be tested based on the results of the comparison. For this purpose, the response analysis unit 372 can manage a corresponding estimated response for each of the test patterns in a database. In other words, the response analysis unit 372 can manage an estimated response for service result provided by the corresponding IED based on a test pattern transmitted from the test pattern transmission unit 371, and compare the response information received from the IED to be tested with the estimated response. If the return information is identified with the estimated information, the fault determination unit 373 determines that the corresponding IED is normal, and otherwise determines that a fault occurred in the corresponding IED based on the results of the comparison.

The result display unit 380 displays the occurrence or non-occurrence of a fault, determined by the fault determination unit 373, on a user interface. Here, the used test pattern, the response information, and the estimated response may be displayed on the user interface with the determined occurrence or non-occurrence of a fault.

As described above, in order to diagnose a fault in the bay IED 112 for the substation automation system 110, the online diagnosis device 142 designates an IED to be tested with reference to an SCD file received from the station device 111 of the substation automation system 110, transmits the backup information for the IED to be tested to the backup IED 141, and determines the occurrence or non-occurrence of a fault in the IED to be tested by analyzing response information, received in response to the transmission of a test pattern to the IED to be tested. Here, the backup IED 141 may replace the operation of the IED to be tested based on the backup information received from the online diagnosis device 142.

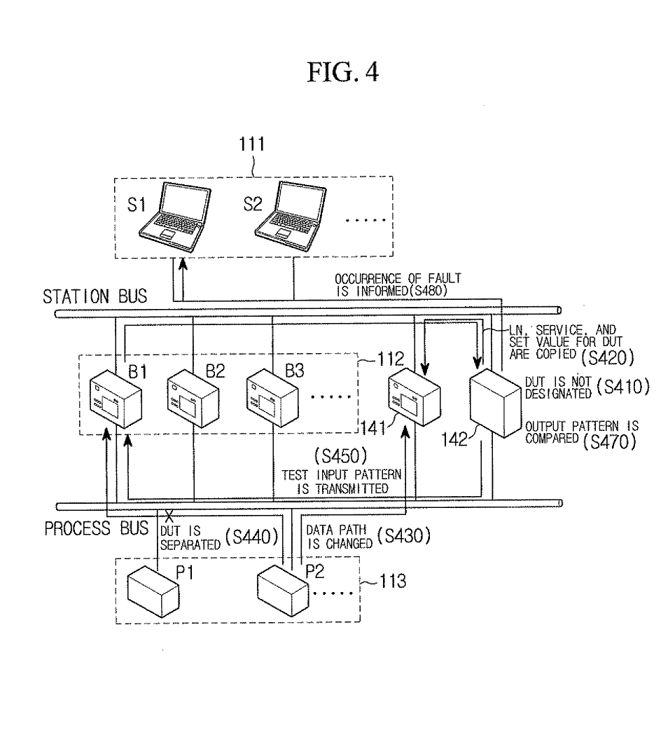

The operation of the fault diagnosis device 140 of FIG. 1 will be described in more detail with reference to the flowchart of FIG. 4 below.

First, in order to diagnose faults in respective bay IEDs 112, the IED selection unit 350 of the fault diagnosis device 140 designates one of IEDs, included in an IED list extracted from a SCD file received from the station device 111, as an IED to be tested (a Device Under Test (DUT)) at step S410. Next, the target IED information transmission unit 361 of the fault diagnosis device 140 extracts backup information for the IED to be tested, for example, service (a control block), a logic node, and a set value, from the IED list, and transmits the extracted backup information to the backup IED 141 at step S420.

H ere, the file processing unit 310 of the backup IED 141 can receive the backup information, and the program management unit 320 of the backup IED 141 can store and manage the backup information, and enable or disable the service function, which is the same as that of the IED to be tested based on the backup information. As described above, the backup IED 141, which received the copied backup information from the IED information transmission unit 361, performs the same function as the IED to be tested while fault diagnosis is performed.

The service control unit 362 of the fault diagnosis device 140 performs control such that service, such as a control block and a data set, included in the online diagnosis device 142 and the backup IED 141, is enabled or disabled. Therefore, the program management unit 320 of the backup IED 141 can enable a program including the backup information such that the backup IED 141 performs the same function as that of the IED to be tested. Further, when diagnosis for the IED to be tested is terminated, the program management unit 320 of the backup IED 141 can disable the program.

As described above, while the backup IED 141 performs the same function as that of the IED to be tested, the corresponding IED (for example, the IED denoted as “B1”) is isolated from the system, that is, input from the corresponding process IED is disabled, at step S440.

Next, the test pattern transmission unit 371 of the fault diagnosis device 140 selects a test pattern to be tested from among test patterns managed in a database, and transmits it to the designated IED to be tested (for example, the IED denoted as “B1”) at step S450. Here, the test pattern can be selected based on the request of a user or can be selected automatically in sequence.

Therefore, the IED to be tested maintains or changes the existing function thereof based on the test pattern transmitted from the test pattern transmission unit 371, provides service, such as monitor, control, and protection for the respective pieces of electric power equipment in the substation, and then returns response information indicating the normal or abnormal state of the system of the respective pieces of electric power equipment based on the results thereof at step S460.

The response analysis unit 372 of the fault diagnosis device 140 receives the response information returned from the IED to be tested, and compares the received response information with an estimated response at step S470. Based on the results of the comparison, the fault determination unit 373 determines that the IED to be tested is normal if the response information is identified with the estimated response, and otherwise determines that a fault has occurred in the IED to be tested.

The occurrence or non-occurrence of a fault, determined by the fault determination unit 373, may be transmitted to and displayed on the user interface (MMI). Here, the used test pattern, the response information, and the estimated response may be displayed on the user interface with the determined occurrence or non-occurrence of a fault at step S480.

If it is determined that the IED to be tested (for example, the IED denoted as “B1”) is normal and it is sound, commands are executed in the reverse order compared to the above-described steps S410 to S440, so that the IED to be tested (for example, the IED denoted as “B1”) is recovered and is operated as it is. Thereafter, an IED (for example, the IED denoted as “B2”) to be inspected next is set to a DUT. Thereafter, as described above, the above-described steps S420 to S470 are performed, so that faults are diagnosed. The above-described method is repeatedly performed on other IEDs, so that the faults of all IEDs included in the system can be diagnosed. Therefore, when a fault occurs in any of the IEDs, an operator who performs monitor using a user interface can rapidly take measures, such as maintenance, for the corresponding IED.

Various modifications and applications of the IED fault diagnosis device and method according to the present invention are possible within the technical scope of the present invention. For example, preferably, the IEDs described in the embodiments are general purpose computers, but can be replaced with dedicated terminal devices or semiconductor chips for monitoring, controlling, or protecting electric power equipment if necessary. Although the preferred embodiments and drawings of the present invention have been disclosed for illustrative purposes, those skilled in the art will appreciate that various modifications, additions and substitutions are possible, without departing from the scope and spirit of the invention as disclosed in the accompanying claims.

As described above, the IED fault diagnosis device and method according to the present invention has an advantage in that a fault which may occur in an IED can be diagnosed while the IED is not separated from the system, the function of the IED is not disabled, and the normal function of the IED is continuously performed during the inspection for the IED.

Further, the IED fault diagnosis device and method according to the present invention accurately and reliably diagnose a fault in an IED without adding additional software or hardware to the IED, thereby having an advantage in that excellent performance can be expected at an inexpensive cost.

Furthermore, the IED fault diagnosis device and method according to the present invention can diagnose a fault in an IED online from outside a substation automation system, and can indicate the soundness of the IED by functioning as part of the substation automation system, thereby having an advantage in that considerable convenience is provided for the operation, such as the maintenance, of a substation.

Furthermore, the IED fault diagnosis device and method according to the present invention, when the occurrence of a fault in a certain IED is determined, causes a backup IED to replace the function of the faulty IED and to perform a backup function, that is, operate until the faulty IED is repaired or exchanged, thereby having an advantage in that duplication effect, such as fault diagnosis and backup, can be expected using the backup IED.

What is claimed is:

1. A fault diagnosis device for diagnosing a fault in a bay Intelligent Electronic Device (IED) for a substation automation system, comprising:
an online IED diagnosis device for, with reference to a Substation Configuration Description (SCD) file received from a station device of the substation automation system, designating an IED to be tested, and extracting backup information for the IED to be tested; and
a backup IED for replacing an operation of the IED to be tested based on the extracted backup information;
wherein the online IED diagnosis device determines occurrence or non-occurrence of a fault in the IED to be tested by analyzing response information received in response to transmission of a test pattern to the IED to be tested.

2. The fault diagnosis device as set forth in claim 1, wherein the online IED diagnosis device comprises:
an IED selection unit for designating the IED to be tested from an IED list extracted from the SCD file;
an IED switch unit for extracting the backup information for the IED to be tested from the IED list, and transmitting it to the backup IED;
a fault diagnosis unit for transmitting the test pattern to the IED to be tested, receiving the response information from the IED to be tested in response to the transmitted test pattern, and determining the occurrence or non-occurrence of a fault in the IED to be tested by analyzing the received response information; and
a result display unit for displaying the determined occurrence or non-occurrence of a fault on a user interface.

3. The fault diagnosis device as set forth in claim 2, wherein the fault diagnosis unit manages an estimated response for a service result provided by the corresponding IED based on the transmitted test pattern, and determines occurrence or non-occurrence of a fault by comparing the received response information with the estimated response.

4. A fault diagnosis device for a substation automation system, the substation automation system including one or more station devices, one or more bay IEDs connected to the station device through a station bus based on an Ethernet, and one or more process IEDs connected to the respective bay IEDs though a process bus based on an Ethernet and configured to manage one or more pieces of electric power equipment of a substation, wherein:
the fault diagnosis device is connected to the station devices, the bay IEDs and the process IEDs based on an Ethernet;
the fault diagnosis device designates an IED to be tested from a bay IED list extracted from an SCD file received from the station device, and causes a backup IED to replace operation of the IED to be tested; and
the fault diagnosis device transmits a test pattern to the IED to be tested, and determines occurrence or non-occurrence of a fault in the IED to be tested by inspecting response information received from the IED to be tested.

5. A fault diagnosis method of diagnosing a fault in a bay IED for a substation automation system, the method comprising:
receiving an SCD file from a station device of the substation automation system;
extracting an IED list from the received SCD file and designating an IED to be tested;
causing a backup IED to replace operation of the IED to be tested based on backup information for the IED to be tested;
transmitting a test pattern to the IED to be tested;
receiving response information from the IED to be tested in response to the transmitted test pattern;
determining occurrence or non-occurrence of a fault in the IED to be tested by inspecting the received response information; and
displaying the determined occurrence or non-occurrence of a fault on a user interface.
